(19) United States
(12) Patent Application Publication
(10) Pub. No.: US 2007/0285889 A1
(43) Pub. Date: Dec. 13, 2007

(54) FORCED AIR COOLED ELECTRICAL BOX FOR MINING EQUIPMENT

(76) Inventors: Mark A. Watson, Lexington, KY (US); Robert E. Watson, Henderson, KY (US)

Correspondence Address: KING & SCHICKLI, PLLC, 247 NORTH BROADWAY, LEXINGTON, KY, 40507, US

(21) Appl. No.: 11/761,701

(22) Filed: Jun. 12, 2007

Related U.S. Application Data
(60) Provisional application No. 60/812,748, filed on Jun. 12, 2006.

(51) Int. Cl. H05K 7/20

(52) U.S. Cl. 361/695

(57) ABSTRACT

An electrical box for mining apparatus and a mining apparatus are provided. The electrical box includes a housing having an explosion proof enclosure and a cooling duct. An electrical circuit is held in the enclosure. A fan is provided for forcing air through the cooling duct.

This application claims priority to prior U.S. Provisional Patent Application Ser. No. 60/812,748 filed 12 Jun. 2006.

### TECHNICAL FIELD

The present invention relates generally to the mining equipment field and, more particularly, to a forced air-cooled electrical box for mining equipment.

### BACKGROUND OF THE INVENTION

Mine locomotives, mobile conveyors, roof bolting machines, scoop tractors, shuttle cars, continuous miners, other mining vehicles and even stationary mining equipment generally rely upon electrical power systems based on alternating current (AC) or direct current (DC). Such mining equipment often utilizes powerful electrical motors which draw a great deal of current through the electrical circuits of the equipment. An unfortunate by-product of all this flowing current is the production of heat. In order to insure proper operation of this equipment, this heat must be efficiently dissipated.

The present invention relates to a forced air-cooled electrical box for mining equipment which allows for enhanced heat dissipation within the harsh and hazardous mine environment in which mining equipment operates

### SUMMARY OF THE INVENTION

In accordance with the purposes of the present invention as described herein, an electrical box is provided. The electrical box comprises a housing including an explosion proof enclosure and a cooling duct. An electrical circuit is held in the enclosure. The electrical box further includes a fan for forcing air through the cooling duct. The electrical box further includes a heat sink that extends into the cooling duct. A thermal conductor connects the electrical circuit in the enclosure to the heat sink. In accordance with one embodiment of the invention the fan is driven by a hydraulic motor.

In accordance with yet another aspect of the present invention, a mining apparatus is provided. The mining apparatus comprises a body, an electric drive motor carried by the body and an electrical box of the type described above.

In accordance with yet another aspect of the present invention a method is provided of cooling an electrical box in a mining apparatus. The method may be broadly described as comprising the step of passing an air stream through the electrical box. More specifically, the method includes providing the electrical box with at least one heat sink and generating the air stream with a fan. Further, the method may include driving the fan with a hydraulic motor.

Alternatively, the method may be described as comprising the steps of providing the electrical box with an explosion proof enclosure for an electrical circuit, providing the electrical box with a cooling duct and providing a fan for passing an air stream through the cooling duct. Still further, the method may include the step of providing a heat sink in the electrical box for conducting heat from the electrical circuit in the enclosure to the air stream in the cooling duct. More specifically, the method may include passing the heat sink through a wall of the enclosure while maintaining the enclosure explosion proof. Further, the method may include driving the fan with a hydraulic motor.

In the following description there is shown and described a preferred embodiment of this invention, simply by way of illustration of one of the modes best suited to carry out the invention. As it will be realized, the invention is capable of other different embodiments and its several details are capable of modification in various, obvious aspects all without departing from the invention. Accordingly, the drawings and descriptions will be regarded as illustrative in nature and not as restrictive.

### BRIEF DESCRIPTION OF THE DRAWING

The accompanying drawing incorporated herein and forming a part of the specification illustrates several aspects of the present invention and together with the description serves to explain certain principles of the invention. In the drawing:

FIG. 1 is a partially schematical, side elevational view of a mining apparatus incorporating the electrical box of the present invention with the front wall of the box removed to reveal the explosion proof enclosure and some of the electrical circuits; and

FIG. 2 is a perspective view of the electrical box.

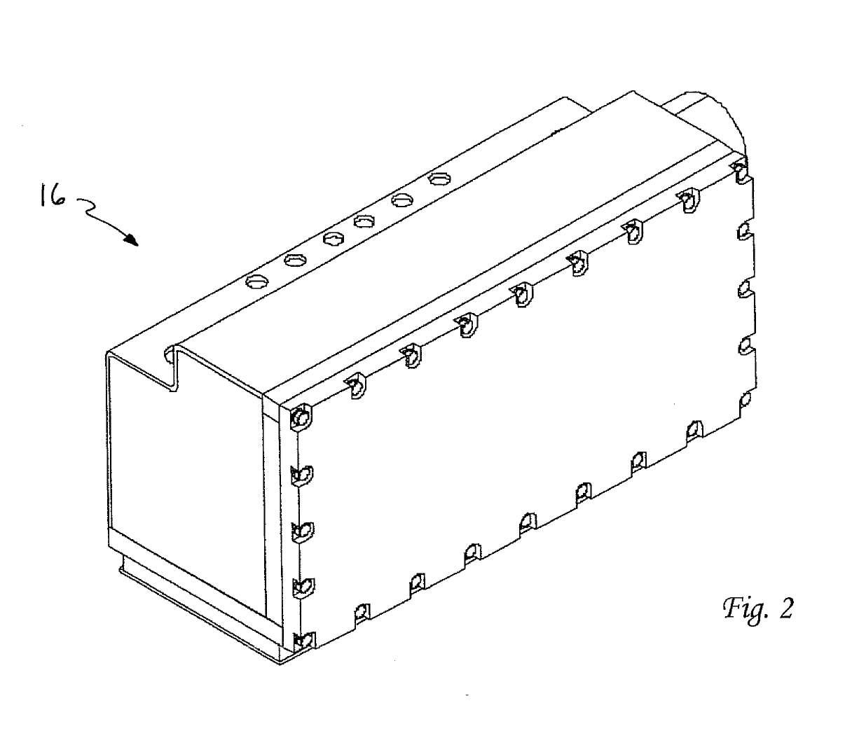

Reference will now be made in detail to the present preferred embodiment of the invention, an example of which is illustrated in the accompanying drawing.

### DETAILED DESCRIPTION OF THE INVENTION

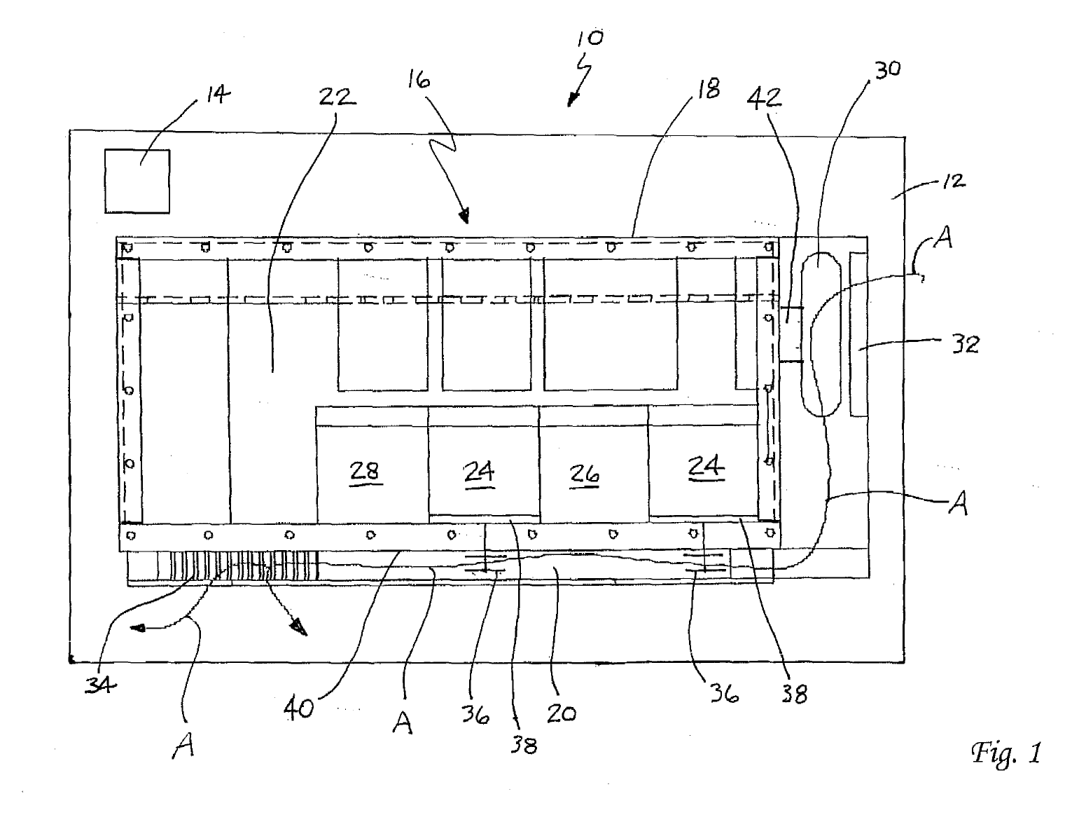

Reference is now made to FIG. 1 which schematically illustrates a mining apparatus 10 such as a mine locomotive, roof bolting machine, mobile conveyor, shuttle car, scoop tractor, continuous miner or the like. The mining apparatus 10 comprises a body 12 that carries an electric drive motor 14 such as a conveyor drive motor, traction drive motor or the like. The body 12 further includes an electrical box 16 including an explosion proof enclosure 18 and a cooling duct 20. The explosion proof enclosure 18 is made in accordance with engineering specifications as set forth in Title 30 C.F.R. § 18.31. The compartment 22 defined by the explosion proof enclosure 18 houses electrical circuits for various systems of the apparatus 10. These include, for example, a tractor drive circuit 24, a pump circuit 26 for the hydraulic system and a motor circuit 28 for driving a conveyor.

A fan 30 is mounted in the electrical box 16 adjacent the explosion proof enclosure 18. The fan 30 draws air through an air filter 32 and then forces that air through the cooling duct 20 to an exhaust outlet 34 (note action arrow A).

As further illustrated in FIG. 1, two optional heat sinks 36 extend into the cooling duct 20. In the illustrated embodiment one heat sink 36 is provided for each of the traction drive circuits 24. Each heat sink 36 is connected to the circuit 24 by means of a thermal conductor 38. Further, each heat sink 36 extends through a wall 40 of the explosion proof enclosure 18 while maintaining the explosion-proof rating required by Title 30 C.F.R. §18.31.

As illustrated, the heat sinks 36 extend into the cooling duct 20 so that the air stream produced by the fan 30 passes through and over the heat sinks 36 thus maximizing the cooling effect and thereby efficiently dissipating heat from the electrical circuits 24 and the electrical box 16. In one possible embodiment the fan 30 is driven by a hydraulic motor 42. This eliminates the need to produce an explosion proof housing for the fan drive.

In summary numerous benefits result from employing the concepts of the present invention. The forced air-cooled electrical box 16 of the present invention may be utilized in substantially any underground mining equipment including but not limited to shuttle cars, tractor-trailers, articulated haulers and scoops. The enhanced cooling provides increased heat dissipation capacity thereby allowing the circuitry to run properly at higher currents. These higher currents allow one to increase the power in the mining equipment so that the equipment is better suited for today's mine applications where difficult mining geology and large mining capacities are the norm. Further, this additional cooling is achieved without resorting to liquid cooling and the associated capital and maintenance costs of such systems.

The foregoing description of a preferred embodiment of the invention has been presented for purposes of illustration and description. It is not intended to be exhaustive or to limit the invention to the precise form disclosed. Obvious modifications or variations are possible in light of the above teachings. The embodiment was chosen and described to provide the best illustrations of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally and equitably entitled.

What is claimed is:

1. An electrical box, comprising:
a housing including an explosion proof enclosure and a cooling duct;
an electrical circuit held in said enclosure; and
a fan for forcing air through said cooling duct.

2. The electrical box of claim 1, further including a heat sink extending into said cooling duct.

3. The electrical box of claim 2, further including a thermal conductor connecting said circuit to said heat sink.

4. The electrical box of claim 1, further including a hydraulic motor for driving said fan.

5. A mining apparatus, comprising;
a body;
an electric drive motor carried by said body;
an electrical box including a housing with an explosion proof enclosure and a cooling duct;
an electrical circuit held in said enclosure; and
a fan for forcing air through said cooling duct.

6. The electrical box of claim 5, further including a heat sink extending into said cooling duct.

7. The electrical box of claim 6, further including a thermal conductor connecting said circuit to said heat sink.

8. The electrical box of claim 5, further including a hydraulic motor for driving said fan.

9. A method of cooling an electrical box on a mining apparatus, comprising:
passing an airstream through said electrical box.

10. The method of claim 9, including providing said electrical box with at least one heat sink.

11. The method of claim 9, including generating said airstream with a fan.

12. The method of claim 11, including driving said fan with a hydraulic motor.

13. A method of cooling an electrical box on a mining apparatus comprising:
providing said electrical box with an explosion proof enclosure for an electrical circuit;
providing a said electrical box with a cooling duct; and
providing a fan for passing an air stream through said cooling duct.

14. The method of claim 13, including providing a heat sink in said electrical box for conducting heat from an electrical circuit in said enclosure to said air stream in said cooling duct.

15. The method of claim 14, including passing said heat sink through a wall of said enclosure while maintaining said enclosure explosion proof.

16. The method of claim 15, including driving said fan with a hydraulic motor.
